(19) United States
(12) Patent Application Publication
(10) Pub. No.: US 2007/0173029 A1
(43) Pub. Date: Jul. 26, 2007

(54) Method for fabricating high performance metal-insulator-metal capacitor (MIMCAP)

(75) Inventors: Wagdi William Abadeer, Jericho, VT (US); Jack Allan Mandelman, Flat Rock, NC (US); Carl John Radens, LaGrangeville, NY (US); William Tonti, Essex Junction, VT (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, ARMONK, NY (US)

(21) Appl. No.: 11/340,340

(22) Filed: Jan. 26, 2006

(51) Int. Cl. H01L 21/20

(52) U.S. Cl. 438/396

(57) ABSTRACT

A method of fabricating a high performance metal-insulator-metal capacitor (MIMCAP) includes providing a first inter-level dielectric (ILD) layer over an isolation region; forming a MIMCAP pattern in the first ILD layer over the isolation region; depositing a conformal conductive liner over the MIMCAP pattern and the first ILD layer; depositing an insulator over the conformal conductive liner; forming a contact pattern through the conformal conductive liner, the insulator and the first inter-level dielectric (ILD) layer; depositing a second conformal conductive liner over the MIMCAP pattern, the contact pattern and the first ILD layer; and depositing a conductive stud over the second conformal conductive liner in the MIMCAP pattern and the contact pattern. The method is applicable to both a conventional bulk semiconductor substrate and a silicon-on-insulator (SOI) substrate.

### FIELD OF THE INVENTION

The present invention relates generally to the field of manufacturing semiconductor devices, and more particularly, relates to a method of fabricating a high performance metal-insulator-metal capacitor (MIMCAP).

### DESCRIPTION OF THE RELATED ART

In manufacturing semiconductor devices, a need exists for integrating a metal-insulator-metal capacitor (MIMCAP) over an isolation region of bulk silicon or silicon-on-insulator (SOI) semiconductor devices. A need exists for an effective method for fabricating such high performance metal-insulator-metal capacitor (MIMCAP).

### SUMMARY OF THE INVENTION

A principal aspect of the present invention is to provide a method for fabricating a high performance metal-insulator-metal capacitor (MIMCAP). Other important aspects of the present invention are to provide such method of fabricating a high performance metal-insulator-metal capacitor (MIMCAP) substantially without negative effect and that overcome many of the disadvantages of prior art arrangements.

In brief, a method of fabricating a high performance metal-insulator-metal capacitor (MIMCAP) includes providing a first inter-level dielectric (ILD) layer over an isolation region; forming a MIMCAP pattern in the first ILD layer over the isolation region; depositing a conformal conductive liner over the MIMCAP pattern and the first ILD layer; depositing an insulator over the conformal conductive liner; forming a contact pattern through the conformal conductive liner, the insulator and the first inter-level dielectric (ILD) layer; depositing a second conformal conductive liner over the MIMCAP pattern, the contact pattern and the first ILD layer; and depositing a respective conductive stud over the second conformal conductive liner in the MIMCAP pattern and the contact pattern.

In accordance with features of the invention, after depositing the conductive studs, a first level metal is formed over the conductive stud in the MIMCAP pattern and the contact pattern by a damascene line wire level process including depositing a second inter-level dielectric (ILD) layer.

In accordance with features of the invention, an initial structure includes a substrate layer, such as a silicon substrate, underlying a buried oxide (BOX) layer, a shallow trench isolation (STI) region is formed using photolithography and reactive ion etch (RIE) processing to pattern SOI regions, which are converted to salicide region (self-aligned silicide), and a barrier layer, such as SiN, is deposited.

In accordance with features of the invention, the method for fabricating a metal-insulator-metal capacitor (MIMCAP) over an isolation region is applicable to both a conventional bulk semiconductor substrate and a silicon-on-insulator (SOI) substrate.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1, 2, 3, 4, 5, and 6 are diagrams not to scale illustrate exemplary process steps for fabricating a high performance metal-insulator-metal capacitor (MIMCAP) in accordance with the preferred embodiment.

### DETAILED DESCRIPTION OF THE PREFERRED EMBODIMENTS

In accordance with features of the preferred embodiments, a fabrication method is provided for fabricating a high performance metal-insulator-metal capacitor (MIMCAP) over an isolation region for use with various semiconductor and integrated circuits devices.

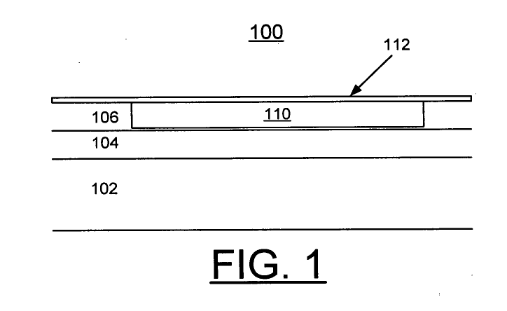

Having reference now to the drawings, in FIGS. 1, 2, 3, 4, 5, and 6, there are shown exemplary process steps for fabricating a high performance metal-insulator-metal capacitor (MIMCAP) in accordance with the preferred embodiment.

In FIG. 1, a first processing step generally designated by the reference character 100 begins with a barrier formation in accordance with the preferred embodiment.

As shown in FIG. 1, an initial structure for the first processing step 100 includes a substrate layer 102, such as a silicon substrate 102, underlying a buried oxide (BOX) layer 104, such as a 150 nm oxide layer. A shallow trench isolation (STI) region 106, of thickness range 5 nm to 200 nm, preferably 50 nm, is formed over the BOX layer 104. A SOI salicide region 110 underlies a barrier layer 112.

The STI region 106 is formed using photolithography and RIE to pattern the SOI regions 110 as is known to those skilled in the art. The SOI region 110 is converted to salicide (self-aligned silicide) by deposition of metal, such as Ni or Co and TiN, thermal reaction, and selective etching to remove unreacted metal from STI 106 leaving the salicide formed from the SOI. The barrier 112, such as SiN, is deposited over the STI region 106 and SOI salicide region 110 using chemical vapor deposition (CVD).

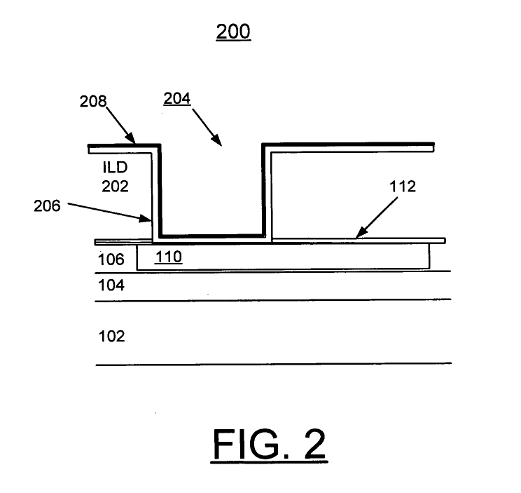

Referring to FIG. 2, there is shown a next MIMCAP pattern-processing step generally designated by the reference character 200 in accordance with the preferred embodiment.

An inter-level dielectric (ILD) layer 202 is oxide deposited by CVD and planarized, if necessary, using a chemical mechanical polishing (CMP) process. A MIMCAP pattern 204 is formed using lithography and reactive ion etch (RIE) processing. A conformal conductive liner 206 and a thin insulator 208 are deposited over the MIMCAP pattern 204.

The conformal conductive liner 206 is formed by sputtering or CVD, or atomic layer deposition (ALD), and is a conductor such as TiN, or TaN, W, Al, Cu, Ni, Co, Ru or a combination thereof. The thin insulator 208 is deposited by CVD or ALD such as oxide, SiN, TaO5, high dielectric constant value k material such as HfO, ZrO, AlO or a combination thereof.

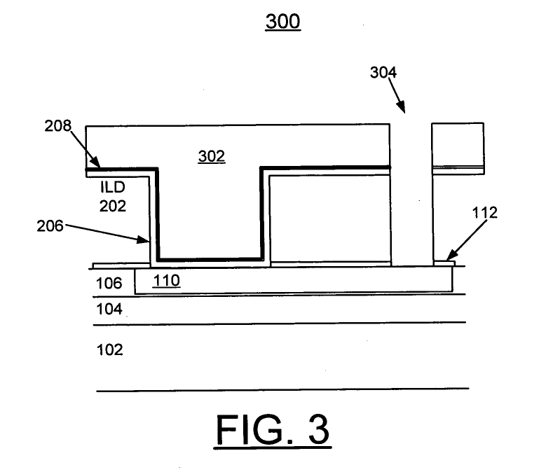

Referring to FIG. 3, there is shown a next processing step generally designated by the reference character 300 in accordance with the preferred embodiment. A resist 302 is deposited and a contact pattern 304 is formed using lithography and reactive ion etch (RIE) processing.

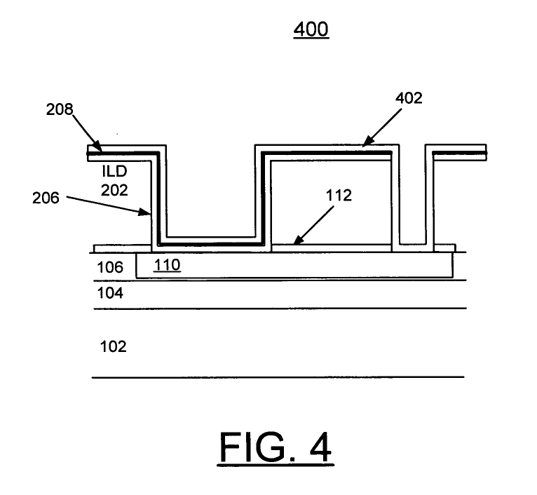

Referring to FIG. 4, there is shown a next processing step generally designated by the reference character 400 in accordance with the preferred embodiment. A second conformal conductive liner 402 is formed using CVD or ALD or sputtering of an electrically conductive material such as TiN, TaN, W, WN, Al, Cu, Ni, Co, Ru or a combination thereof.

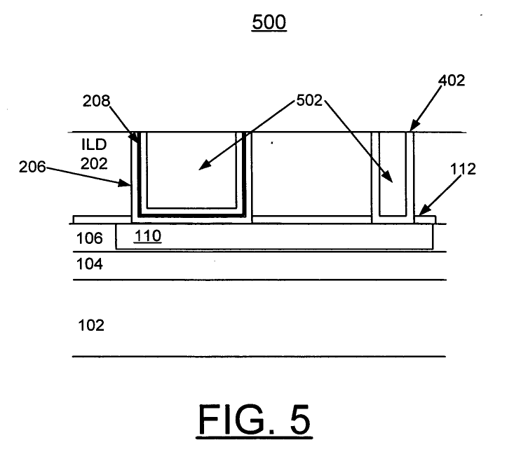

Referring to FIG. 5, there is shown a next processing step generally designated by the reference character 500 in accordance with the preferred embodiment. A conductive stud 502 formed of a suitable electrically conductive material, for example, of tungsten (W) deposited by CVD, and/or Cu deposited by a combination of CVD, sputtering and plating, which is then planarized by CMP.

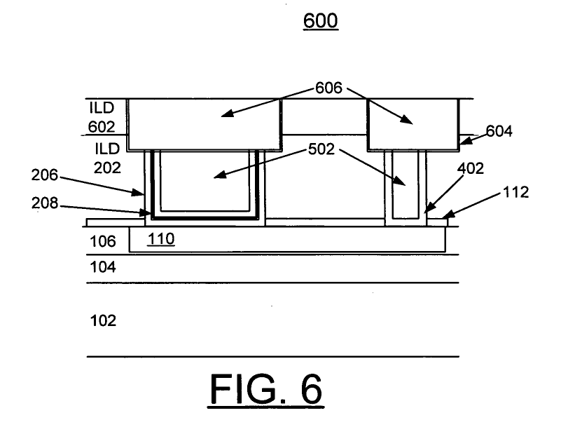

Referring to FIG. 6, there is shown a final processing step generally designated by the reference character 600 in accordance with the preferred embodiment forms the MIMCAP. Processing step 600 is a standard damascene line wire level process. A wire level (Ml) inter-level dielectric (ILD) layer 602 is deposited, for example, by CVD. An interconnect wiring level is patterned using photolithography and RIE, and a conductive liner 604, and a damascene line pattern filled with conductor 606 are deposited and planarized using CMP to complete a MIMCAP structure of the preferred embodiment.

While the present invention has been described with reference to the details of the embodiments of the invention shown in the drawing, these details are not intended to limit the scope of the invention as claimed in the appended claims.

What is claimed is:

1. A method for fabricating a metal-insulator-metal capacitor (MIMCAP) comprising the steps of:
providing a first inter-level dielectric (ILD) layer over an isolation region;
forming a MIMCAP pattern in said first ILD layer over said isolation region;
depositing a first conformal conductive liner over said MIMCAP pattern and said first ILD layer;
depositing an insulator over said first conformal conductive liner;
forming a contact pattern through said conformal conductive liner, said insulator and said first inter-level dielectric (ILD) layer;
depositing a second conformal conductive liner over said MIMCAP pattern, said contact pattern and said first ILD layer; and
depositing a conductive stud over said second conformal conductive liner in said MIMCAP pattern and said contact pattern.

2. A method for fabricating a metal-insulator-metal capacitor as recited in claim 1 includes forming a first level metal layer on said conductive stud in said MIMCAP pattern and said contact pattern.

3. A method for fabricating a metal-insulator-metal capacitor as recited in claim 2 wherein forming said first level metal layer includes a damascene line wire level process including depositing a second inter-level dielectric (ILD) layer.

4. A method for fabricating a metal-insulator-metal capacitor as recited in claim 1 includes providing an initial structure defining said isolation region; said initial structure including a substrate, and a buried oxide layer; and forming shallow trench isolation (STI) regions to pattern SOI regions on said buried oxide layer; and converting said SOI regions to salicide (self-aligned silicide) regions.

5. A method for fabricating a metal-insulator-metal capacitor as recited in claim 4 wherein converting said SOI regions to salicide (self-aligned silicide) includes deposition of metal, thermal reaction, and selective etching.

6. A method for fabricating a metal-insulator-metal capacitor as recited in claim 4 includes forming a barrier layer over said STI regions and said salicide regions.

7. A method for fabricating a metal-insulator-metal capacitor as recited in claim 6 wherein forming said barrier layer includes depositing SiN using chemical vapor deposition (CVD).

8. A method for fabricating a metal-insulator-metal capacitor as recited in claim 1 wherein providing said first inter-level dielectric (ILD) layer includes depositing said first inter-level dielectric (ILD) layer using chemical vapor deposition (CVD) over said isolation region.

9. A method for fabricating a metal-insulator-metal capacitor as recited in claim 1 wherein forming said MIMCAP pattern includes forming said MIMCAP pattern in said first ILD layer over said isolation region using lithography and reactive ion etch (RIE) processing.

10. A method for fabricating a metal-insulator-metal capacitor as recited in claim 1 wherein depositing said first conformal conductive liner includes using selected one of sputtering, chemical vapor deposition (CVD), atomic level deposition (ALD).

11. A method for fabricating a metal-insulator-metal capacitor as recited in claim 1 wherein depositing said first conformal conductive liner includes depositing a selected material or a combination of materials selected from a group consisting of TiN, TaN, W, Al, Cu, Ni, Co, and Ru.

12. A method for fabricating a metal-insulator-metal capacitor as recited in claim 1 wherein depositing said insulator over said first conformal conductive liner using a selected one of chemical vapor deposition (CVD), atomic level deposition (ALD).

13. A method for fabricating a metal-insulator-metal capacitor as recited in claim 1 wherein depositing said insulator over said first conformal conductive liner includes depositing a selected material or a combination of materials selected from a group consisting of an oxide, SiN, TaO5, HfO, ZrO, and AlO.

14. A method for fabricating a metal-insulator-metal capacitor as recited in claim 1 wherein forming said contact pattern through said conformal conductive liner, said insulator and said first inter-level dielectric (ILD) layer includes depositing a resist; and forming said contact pattern using lithography and reactive ion etch (RIE) processing.

15. A method for fabricating a metal-insulator-metal capacitor as recited in claim 1 wherein depositing said second conformal conductive liner over said MIMCAP pattern, said contact pattern and said first ILD layer includes using selected one of sputtering, chemical vapor deposition (CVD), atomic level deposition (ALD).

16. A method for fabricating a metal-insulator-metal capacitor as recited in claim 1 wherein depositing said second conformal conductive liner over said MIMCAP pattern, said contact pattern and said first ILD layer includes depositing a selected material or a combination of materials selected from a group consisting of TiN, TaN, W, Al, Cu, Ni, Co, and Ru.

17. A method for fabricating a metal-insulator-metal capacitor as recited in claim 1 wherein depositing said conductive stud over said second conformal conductive liner in said MIMCAP pattern and said contact pattern includes depositing said conductive stud formed of tungsten using chemical vapor deposition (CVD).

18. A method for fabricating a metal-insulator-metal capacitor (MIMCAP) comprising the steps of:
providing an initial structure; said initial structure including a substrate, and a buried oxide layer;
forming shallow trench isolation (STI) regions to pattern SOI regions on said buried oxide layer; and converting said SOI regions to salicide (self-aligned silicide) regions for defining an isolation region;
forming a barrier layer over said STI regions and said salicide regions;
providing a first inter-level dielectric (ILD) layer over said isolation region;
forming a MIMCAP pattern in said first ILD layer over said isolation region;
depositing a first conformal conductive liner over said MIMCAP pattern and said first ILD layer;
depositing an insulator over said first conformal conductive liner;
forming a contact pattern through said conformal conductive liner, said insulator, said first inter-level dielectric (ILD) layer and said barrier layer;
depositing a second conformal conductive liner over said MIMCAP pattern, said contact pattern and said first ILD layer; and
depositing a conductive stud over said second conformal conductive liner in said MIMCAP pattern and said contact pattern.

19. A method for fabricating a metal-insulator-metal capacitor (MIMCAP) as recited in claim 18 includes forming a first level metal layer on said conductive stud in said MIMCAP pattern and said contact pattern.

20. A method for fabricating a metal-insulator-metal capacitor (MIMCAP) as recited in claim 19 wherein forming said first level metal layer includes a damascene line wire level process including depositing a second inter-level dielectric (ILD) layer.
